(19) United States
(12) Patent Application Publication
(10) Pub. No.: US 2013/0321990 A1
(43) Pub. Date: Dec. 5, 2013

(54) LATCHING ASSEMBLY AND ELECTRONIC DEVICE USING THE SAME

(71) Applicants: SHENZHEN FUTAIHONG PRECISION INDUSTRY CO., LTD., (US); FIH (HONG KONG) LIMITED, Kowloon (HK)

(72) Inventors: HUAN-CHANG CHUNG, Shindian (TW); GANG YANG, Shenzhen (CN); HUA-XIANG LIANG, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/859,517

(22) Filed: Apr. 9, 2013

(30) Foreign Application Priority Data
Jun. 1, 2012 (CN) 201210177640.0

(51) Int. Cl. H05K 5/00

(52) U.S. Cl. CPC H05K 5/0013
USPC 361/679.01

(57) ABSTRACT

A latching assembly is used in an electronic device. The electronic device includes a first housing and a second housing. The latching assembly includes at least a pair of latching elements and at least a pair of locking elements corresponding to the latching elements. Each latching element includes a hook located in the first housing, and a catch member defined in the second housing. Each locking element includes a movable member received in the first housing. Each hook clasps one of catch members to engage the first housing and the second housing. Then the movable member moves to the second housing to resist against the hook, thereby limiting the movement of the hook relative to the catch member. An electronic device using the latching assembly is also described.

### CROSS-REFERENCE TO RELATED APPLICATIONS

This application is related to co-pending U.S. Patent Application (Attorney Docket No. US45896), entitled “LATCHING ASSEMBLY AND ELECTRONIC DEVICE USING THE SAME.” Such application has the same assignee as the present application. The above-identified application is incorporated herein by reference.

### BACKGROUND

1. Technical Field

The present disclosure generally relates to latching assemblies, and particularly to a latching assembly used in an electronic device and the electronic device.

2. Description of Related Art

Housings of electronic devices (such as mobile phones) are commonly assembled using screws or by latching structures. However, screws are difficult to be detached when the electronic devices need to be disassembled (to repair or change batteries for example). The latching structure commonly includes conventional hooks. The hooks are configured for engaging in slots of the housing to assemble the electronic device. However, the engagement between the hooks and the slots is prone to loosen when the electronic device is impacted or dropped, which can result in unwanted disassembly.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an exploded view of a latching assembly used in an electronic device in accordance with an exemplary embodiment, the electronic device includes a first housing and a second housing.

FIG. 2 is a schematic view of the second housing of FIG. 1.

FIG. 3 is an assembly view of the electronic device of FIG. 1.

FIG. 4 is a cross-sectional view of the electronic device of FIG. 3 along line IV-IV.

FIG. 5 is a schematic view of the electronic device of FIG. 4 with the latching assembly in a latched state.

FIG. 6 is a schematic view of disassembling the latching assembly of FIG. 5 using magnets.

### DETAILED DESCRIPTION

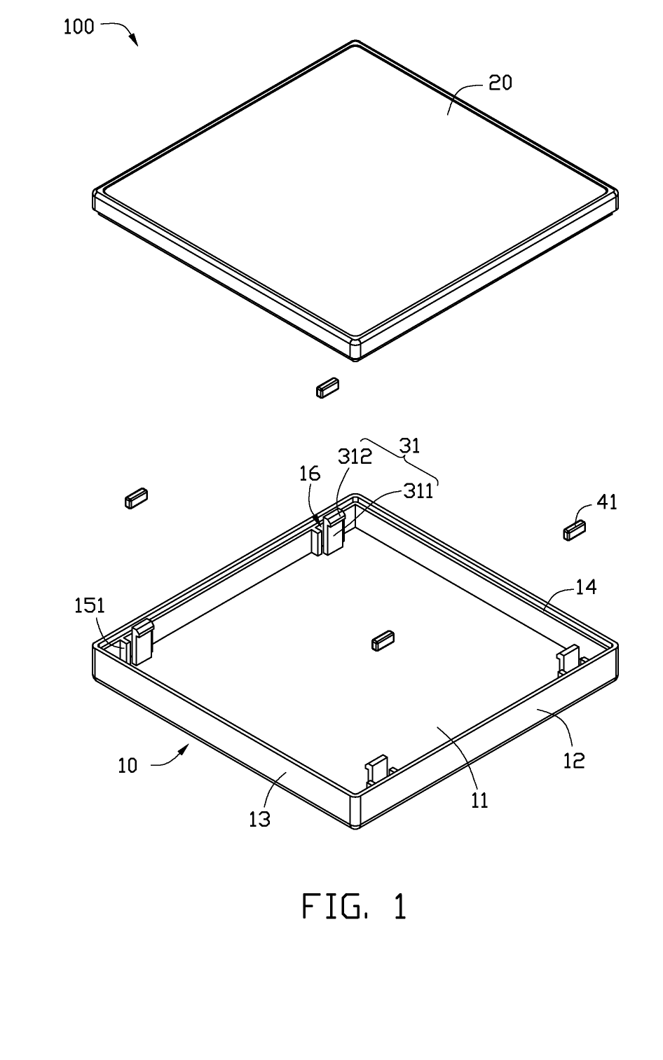

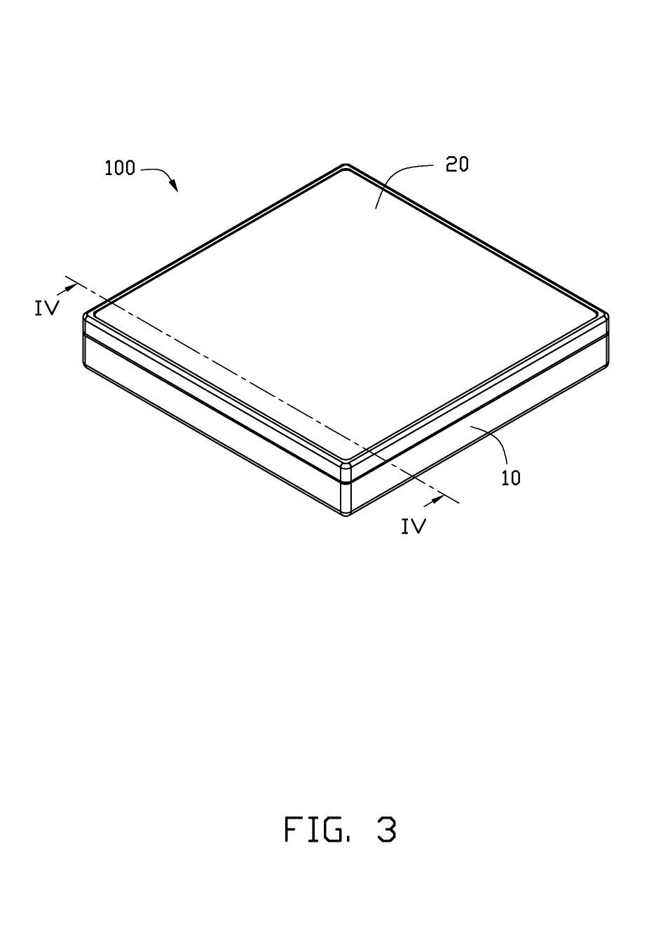

FIGS. 1-3 show a latching assembly used in an electronic device 100 (for example, a mobile phone). The mobile phone is an exemplary application for the purposes of describing details of an exemplary embodiment of a latching assembly. The electronic device 100 includes a first housing 10 and a second housing 20. The latching assembly incorporates the first housing 10 and the second housing 20.

The housing 10 includes a bottom wall 11, two parallel sidewalls 12, and two parallel end walls 13. The two sidewalls 12 and the two end walls 13 connect each other end-to-end. The housing 10 further includes four resisting panels 14 each abutting against the inner surfaces of the two sidewalls 12 and the two end walls 13. At least a pair of blocks 151 protrudes from one of resisting panels 14 abutted the sidewalls 12, adjacent to an end wall 13. In the embodiment, the two resisting panels 14 respectively defines two pairs of blocks 151.

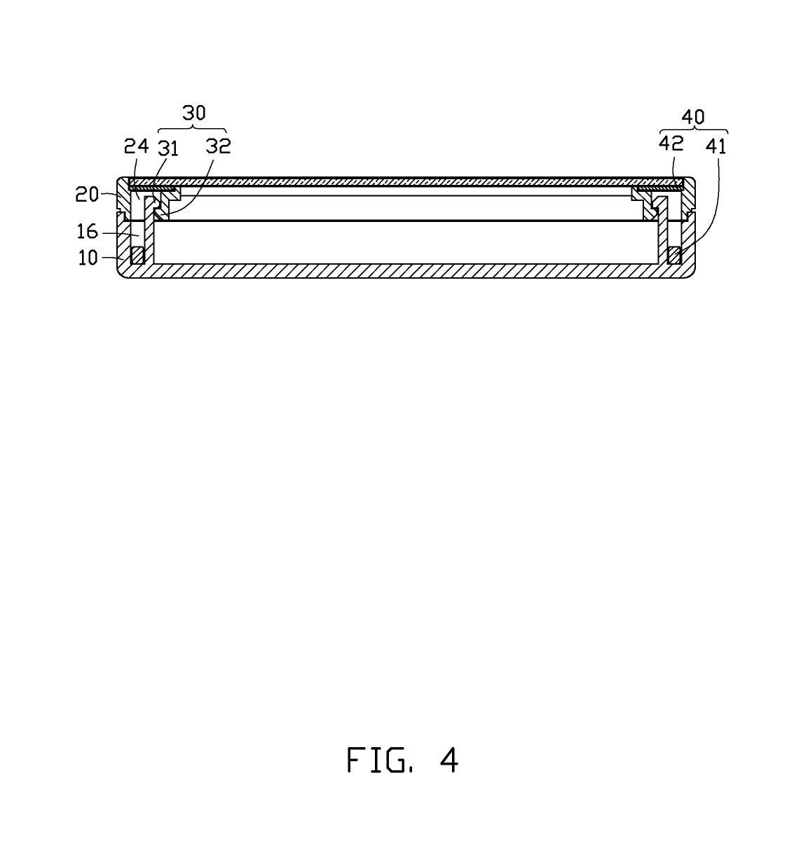

Also referring to FIG. 4, the latching assembly includes at least a pair of latching elements 30 and at least a pair of locking elements 40 corresponding to the latching elements 30. In the embodiment, there are two pairs of latching elements 30 and two pairs of locking elements 40. Each latching element 30 includes a hook 31 located on the bottom wall 11 of the first housing 10, and a catch member 32 defined on the second housing 20. Each hook 31 clasps a corresponding catch member 32 to engage the first housing 10 and the second housing 20, simultaneously the locking elements 40 lock the hooks 31 and the catch members 32.

FIG. 1 shows that each hook 31 includes a main portion 311 and a hooked portion 312 defined at the free end of the main portion 311. Each hook 31 is located between a pair of blocks 151 and is perpendicular to the blocks 151, thereby defining a receiving area 16.

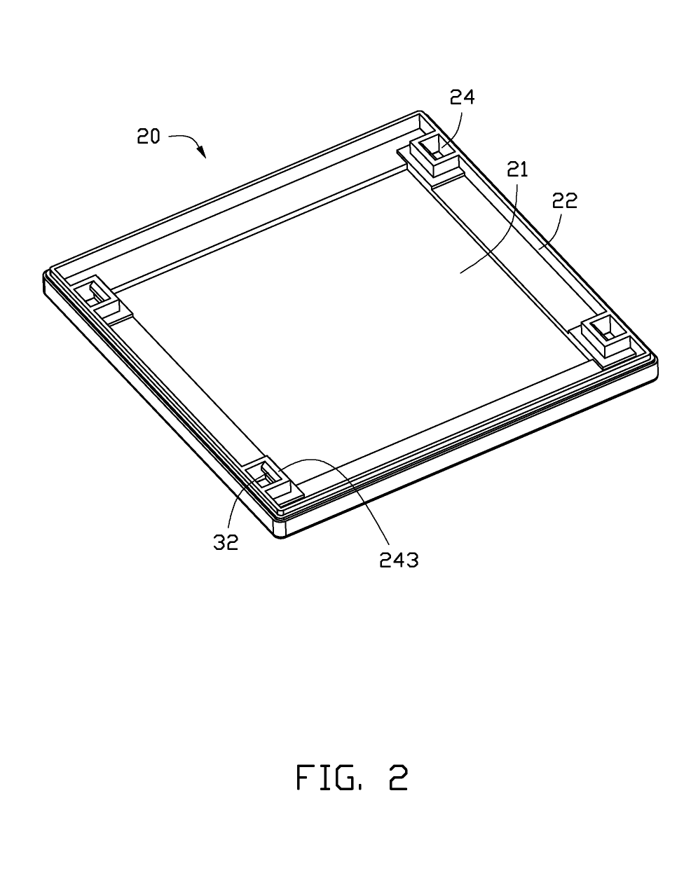

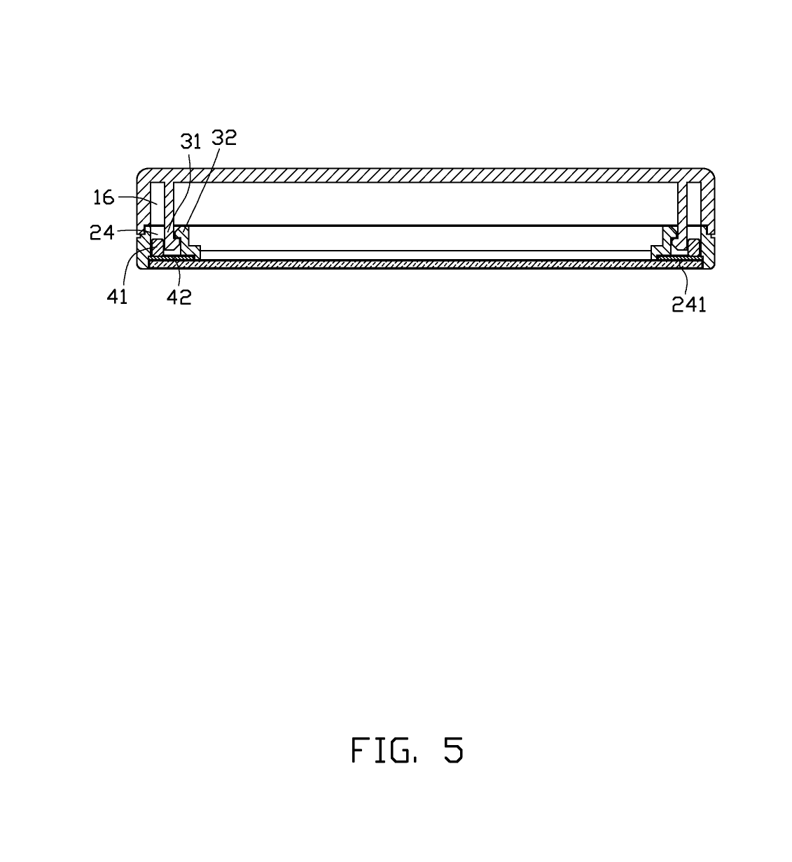

FIG. 2 shows that the second housing 20 includes a plate 21, a peripheral wall 22 perpendicularly protruded from the plate 21, and at least a pair of receiving spaces 24 for receiving the moving members 41. In the embodiment, there are two pairs of receiving spaces 24 corresponding to the receiving areas 16. Each receiving space 24 is located on the plate 21 and abuts against the peripheral wall 22. Each receiving space 24 defines a lower wall 241 (see FIG. 5) and a receiving sidewall 243 facing the peripheral wall 22. Each catch member 32 is defined in a receiving space 24, abutting the receiving sidewall 243.

FIG. 4 shows that each locking element 40 includes a movable member 41 and a fixing member 42. The fixing member 42 is fastened on the lower wall 241 and positioned between the lower wall 241 and the catch member 32. Each movable member 41 is received in a corresponding receiving area 16. The movable member 41 can move from the receiving area 16 into the receiving space 24 and attach to the fixing member 42 to resist against the hooked portion 312 of the hook 31, thereby limiting the movement of the hook 31 relative to the catch member 32, and locking the latching element 30 (see FIG. 5). In the embodiment, the movable member 41 is a magnet, the fixing member 42 is a metal film or a metal sheet made of iron. The movable member 41 is attached to the fixing member 42 by magnetic attraction.

During assembly of the electronic device 100 (see FIG. 4), first, each movable member 41 is received in a corresponding receiving area 16. The second housing 20 is covered on the first housing 10 and pressed towards the first housing 10, allowing each receiving area 16 to communicate a corresponding receiving space 24 and forming a cavity. Each hooked portion 312 of a hook 31 enter a corresponding receiving space 24 to catch a corresponding catch member 32, thereby the first housing 10 and the second housing 20 are connected. Then the first housing 10 and the second housing 20 are rotated 180° (see FIG. 5), making the movable members 41 move in the cavities into the receiving spaces 24 to be magnetically attracted by the fixing members 42. At this time, the movable members 41 resist against the hooked portions 312, thereby limiting the movement of the hooks 31 relative to the catch members 32, and locking the latching elements 30. As a result, even if the electronic device 100 is impacted or dropped, the first housing 10 and the second housing 20 will not loosen from each other.

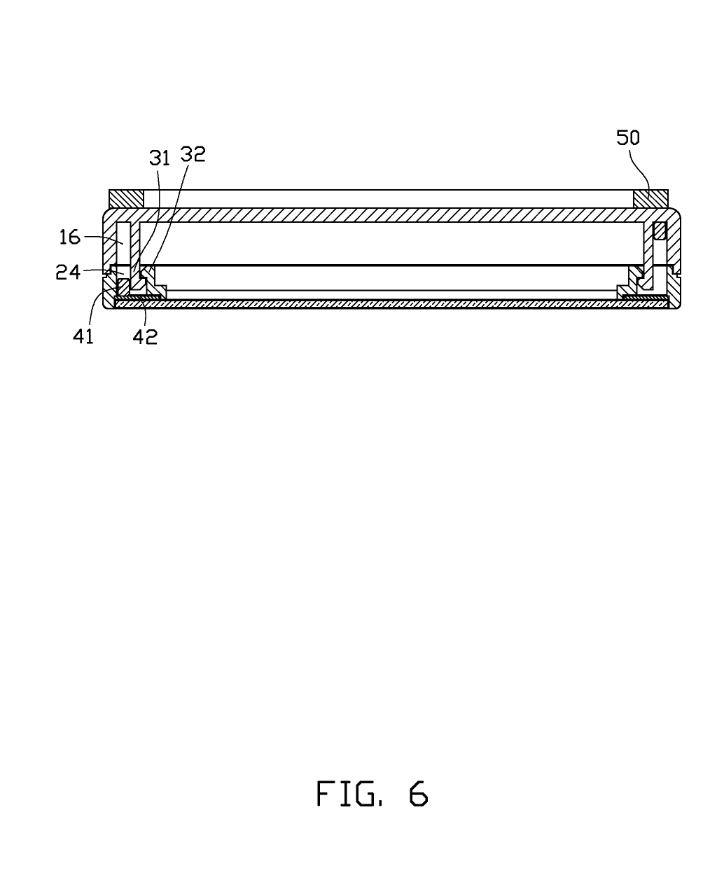

Referring to FIG. 6, to disassemble the first housing 10 and the second housing 20, an external magnet 50, stronger than the magnets 41, is placed on the first housing 10 corresponding to each receiving area 16 to attract the movable members 41 moving to the receiving areas 16 again, thereby unlocking the locking elements 40, then the second housing 20 can be detached from the first housing 10. The magnet 50 can be several magnets arranged in a frame about the same size as the first housing 10, so that the frame is placed over the housings 10, 20 and aligned with the sides so that the magnets are aligned with the cavities.

It is to be understood that, the fixing members 42 of the locking elements 40 can be omitted.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A latching assembly used in an electronic device, the electronic device comprising a first housing and a second housing, the latching assembly comprising:
at least a pair of latching elements, each latching element comprising a hook located in the first housing, and a catch member defined in the second housing; and
at least a pair of locking elements corresponding to the latching elements, each locking element comprising a movable member received in the first housing;
wherein each hook clasps one of catch members to engage the first housing and the second housing, the movable member is capable of moving to the second housing to resist against the hook, thereby limiting the movement of the hook relative to the catch member.

2. The latching assembly as claimed in claim 1, wherein each locking element further comprises a fixing member fastened in the second housing, the movable member is capable of moving to the second housing to attach to the fixing member, and resists against the hook.

3. The latching assembly as claimed in claim 2, wherein each movable member is a magnet, each fixing member is a metal film or a metal sheet made of iron, the movable member is attached to the fixing member by magnetic attraction.

4. The latching assembly as claimed in claim 1, wherein each hook comprises a main portion and a hooked portion defined at the free end of the main portion, each main portion configure with the first housing to define a receiving area, each movable member is movably received in a receiving area.

5. An electronic device, comprising:
a first housing;
a second housing corresponding to the first housing; and
a latching assembly, the latching assembly comprising:
at least a pair of latching elements, each latching element comprising a hook located in the first housing, and a catch member defined in the second housing; and
at least a pair of locking elements corresponding to the latching elements, each locking element comprising a movable member received in the first housing;
wherein each hook clasps one of catch members to engage the first housing and the second housing, the movable member is capable of moving to the second housing to resist against the hook, thereby limiting the movement of the hook relative to the catch member.

6. The electronic device as claimed in claim 5, wherein each locking element further comprises a fixing member fastened in the second housing, each movable member is a magnet, each fixing member is a metal film or a metal sheet made of iron, the movable member is capable of moving to the second housing to magnetically attach to the fixing member, and resist against the hook.

7. The electronic device as claimed in claim 6, wherein the first housing comprises two parallel sidewalls, and at least two panels respectively abut the inner surface of the sidewalls, at least a pair of blocks are protruded from each resisting panel, and towards the other resisting panel, each hook comprises a main portion and a hooked portion defined at the free end of the main portion, the main portion is located between a pair of blocks and is perpendicular to the blocks, thereby defining a receiving area, the movable member is movably received in the receiving area.

8. The electronic device as claimed in claim 7, wherein the first housing further comprises a bottom wall and two parallel end walls, the sidewalls and the end walls are perpendicularly protruded from the bottom wall, the sidewalls and the end walls connect each other end-to-end.

9. The electronic device as claimed in claim 7, wherein the second housing comprises at least a pair of receiving spaces corresponding to the receiving areas, each catch member is defined in a receiving space, each hooked portion of the hook clasps the catch member in the receiving space, each receiving area cooperates a corresponding receiving space to form a cavity for the movement of the movable member of the locking element.

10. The electronic device as claimed in claim 9, wherein the second housing comprises a plate and a peripheral wall perpendicularly protruded from the plate, each receiving space is located on the plate and abuts the peripheral wall, each receiving space defines a lower wall and a receiving sidewall facing the peripheral wall, the fixing member is fastened on the lower wall and positioned between the lower wall and the catch member, each catching element abuts a receiving sidewall.

11. A latching assembly used in an electronic device, the electronic device comprising a first housing and a second housing, the latching assembly comprising:
at least a pair of latching elements, each latching element comprising a hook defined in the first housing, and a catch member defined in the second housing; and
at least a pair of locking elements corresponding to the latching elements, each locking element comprising a movable member received in the first housing;
wherein each hook clasps a corresponding catch member to connect the first housing and the second housing, each movable member is capable of moving to the second housing to resist against a corresponding hook to lock a corresponding latching element.

12. The latching assembly as claimed in claim 11, wherein each locking element further comprises a fixing member fastened in the second housing, the movable member is capable of moving to the second housing to attach to the fixing member, and resists against the hook.

13. The latching assembly as claimed in claim 12, wherein each movable member is a magnet, each fixing member is a metal film or a metal sheet made of iron, the movable member is attached to the fixing member by magnetic attraction.

14. The latching assembly as claimed in claim 11, wherein each hook comprises a main portion and a hooked portion defined at the free end of the main portion, each main portion configure with the first housing to define a receiving area, each movable member is movably received in a receiving area.
